(19) United States
(12) Patent Application Publication
(10) Pub. No.: US 2008/0205521 A1
(43) Pub. Date: Aug. 28, 2008

(54) Dpcm Coding Method of Video Signals

(75) Inventor: Renatus Josephus Van Der Vleuten, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/912,333

(22) PCT Filed: Apr. 12, 2006
(86) PCT No.: PCT/IB2006/051125

§ 371 Date: Oct. 23, 2007

(30) Foreign Application Priority Data
Apr. 27, 2005 (EP) 05103441.1

(51) Int. Cl. H04N 7/34; G06T 9/00; H04N 1/417; H03M 7/00

(52) U.S. Cl. 375/240.14

(57) ABSTRACT

In a method for coding and decoding indicator data (d(x, y), S) are compared to a criterion (T). If the indicator data meet the criterion, an absolute value (Hival/Loval) is inserted instead of a predicted value based on differential coding. This amounts to a bypass of the differential coding loop, which reduces or eliminates oscillatory behavior in such loop, thereby reducing smearing of text parts of a compound image. The absolute values are preferably dynamically determined on the basis of previous predicted values.

The invention relates to a method for coding data using a predictive coding method, in which predictive coding method a difference value representing a difference between a predicted value and an actual value is generated wherein the difference value and a predicted value are used to generate a reconstructed value which reconstructed value is used to predict a novel predicted value.

The invention also relates to a method of decoding data generated by a predictive coding method, said data comprising a difference value wherein the difference value is used to generate on the basis of a predicted value a reconstructed value which reconstructed value is used to predict a novel predicted value.

The invention also relates to a system comprising an encoder for coding data using a predictive coding method and to a system comprising a decoder for decoding data using a predictive coding method.

The invention also relates to an encoder for coding data using a predictive coding method and to a decoder for decoding data using a predictive coding method.

A method, system, encoder and decoder as described in the opening paragraph are known form European Patent application EP 0 599 124.

In predictive coding, also called differential coding, such as a DPCM coding method, the transmitter and the receiver process the data in some fixed order (for instance raster order, row by row and left to right within a row). The current data is predicted from preceding data, which have been reconstructed. DPCM is a coding method used to compress data. In the DPCM (Differential Pulse Code Modulation) method a difference value between the actual value and a predicted value, usually derived from one or more of the previous values, is coded. Usually the differences values are quantized. The difference values are used to generate reconstructed values on the basis of the predicted values. A predictor is used to provide a prediction value based on the reconstructed values. The predictive coding/decoding method comprises a calculation loop, both in coding and in decoding.

DPCM is usually optimized for the compression of natural images, i.e. used for video signal in which case the values are e.g. pixel values.

When large differences values between successive actual pixel values occur, such as for instance when an edge is present in the image, the DPCM method may result in oscillations, so-called overshoot. This leads to a smearing of the edge in the coded bitstream and subsequently in the decoded image. In the described prior art document EP 0 599 124 an attempt has been made to reduce the occurrence of such oscillations by either deriving the prediction value from more than one previous prediction value or, in case an edge is encountered, from only one previous prediction value. This reduces at least partly the occurrence of oscillations.

Although the known method does have some success overshoot is not removed.

The smearing of the edges is in particular visible and objectionable in compound images. For application in image (or video) compression, DPCM is usually optimized for the compression of “natural” images (such as typical holiday pictures and movies). However, with the advance of digital technology and the associated convergence that is occurring between the CE and PC domains, more and more “compound” images are appearing (for example in games). Such images consist of a mix of natural image content and graphics or text (such as sub-titles). The smearing of the edge in a text or graphics part of a compound image is particularly objectionable, since the edges in the text parts are very sharp, so the overshoot is relatively large and clearly visible and before the edge can converge the next edge occurs.

It is an object of the invention to provide a method, system, encoder and decoder as described in the opening paragraph for which the problem of overshoot is reduced.

To this end the coding and the decoding method is characterized in that in the method of coding respectively of decoding indicator data are compared to a criterion and, if the indicator data meet the criterion, a fixed value is inserted for a value reconstructed from the difference value and a predicted value.

The decoder and encoder are characterized in that they comprise a controller and a switch wherein the controller controls the switch to switch to and from inserting a fixed value for a value reconstructed from the difference value and a predicted value.

A system in accordance with the invention has a decoder and/or encoder in accordance with the invention.

The invention is based on the insight that it is advantageous to replace the reconstructed value by a fixed value e.g. when a sharp edge is encountered, i.e. to switch from a differential coding method to an absolute coding method and vice versa. For subtitles the fixed value may e.g. be white 255 or 240 value. Instead of coding and decoding differentially, the method codes and decodes absolutely (i.e. a fixed value is taken instead of the reconstructed value) if the indicator data meet a criterion. Below several examples of data and criteria are given. Indicator data are those data within the bitstream that are compared to a criterium. In the encoder and decoder the indicator data are the input for the controller. The indicator data may be data specifically generated for this purpose, or may be data which are present in the bitstream or generated from data in the bitstream.

The standard DPCM method comprises a feedback loop arrangement. When a large sharp edge occurs in the image, i.e. a step from for instance black to white, a large difference value occurs, which may trigger an oscillatory behavior in the feedback loop. By fixing the value instead of using the reconstructed value, the value is momentary pinned to a fixed value thereby eliminating the oscillatory behavior. In a sense, the DPCM loop is then bypassed. If the criterion is met, a switch is flipped whereby the DPCM loop is bypassed and a fixed value is coded.

One of the insights of the invention is that although to some extent bypassing of the DPCM loop and inserting instead a fixed value, may cause some image quality loss in ‘natural image” parts of a compound images, in such natural image parts sharp edges only rarely occur and even more rarely occur in a clear recognizable pattern, and thus the ‘natural image part’ of a compound image is hardly or only to a minor degree effected. The positive effects the method in accordance with the invention has on the text parts of the compound image are much more prominent that any negative effects it may have on the natural image parts of the compound image.

The criterion for the indicator data is preferably related to the occurrence of an edge in the image.

A simple, yet in practice very useful, criterion is found to be when the difference value exceeds a threshold value. The criterion is simply that the difference value (which in such embodiments forms the data that are compared to a criterion) exceeds a threshold value. More complex criteria relating to more complex set of data may be used within the concept of the invention, such as for instance that a pair or a larger number of subsequent difference values meet certain criteria, in which case the to be compared data are formed by a pair or a larger number of difference values. The “switching data” may, at the decoder end, also be a separate “switching signal” generated by an encoder, in which case the data to be compared is formed by the switching signal and the criterion is the presence (or not) of the ‘switching signal”. The basic concept of the invention remains that, when a criterion is met by data, e.g. difference value (or difference values) meet one or more criteria or separate switching signal meets the criterion of being present, the feedback loop is bypassed and a fixed value is inserted for the reconstructed value, or in other words, the switch is flipped.

In very simple embodiments a fixed absolute value is inserted only when a difference value of a particular sign, either positive or negative, meets a criterion. Large steps in difference may occur when going from a large actual value to a small actual one, or vice versa. In such a simple embodiment for only one type of large difference a fixed absolute value instead of the reconstructed value is coded. In embodiments a single fixed high or low reconstructed value may be used, e.g. only a white 255 or 240 value or a black value. In such embodiments the problem is eliminated for one type of sharp edge. In such simple embodiments preferably a high fixed reconstructed value is taken when the difference value exceeds the threshold.

The positive effects of the invention, i.e. reduction of the smearing effect, are present for any sharp edge, but not always equally apparent. “Smearing” effects may be considerably more visible on a white background than on a black background. Thus in certain circumstances, the positive effect of the invention, or at least the major part of it, may be obtained by a very simple embodiment in which only one type (either positive or negative) of large difference value triggers a bypass of the DPCM loop.

In another, more preferred, embodiment a fixed absolute value is inserted when a difference value of any sign meets the criterion. A fixed high or low absolute value is inserted, dependent on the sign of the difference value. A high (e.g. “white”) and a low (e.g. “black”) fixed value are used. The overshoot is then eliminated or at least reduced at any sharp edge, whether from low to high, or vice versa. The criterion may be basically the same for difference values of positive and negative sign. This is a simple embodiment. Within the framework of the invention different criteria may be set for difference values of different signs.

In a first, simple embodiment the absolute value is a simple fixed value, which cannot be adjusted, for instance a high value for white and/or a low value for black. This embodiment is advantageous for instance when it is known that black and white text is used, for instance in subtitling, i.e. when it is a priori rather clear what a good choice for the fixed values are.

In more sophisticated embodiments of the invention the method comprises a step in which the absolute values are updated, preferably from previously reconstructed values. Initial fixed values are used, e.g. white 255 or 240, but the fixed values are updated preferably using previously reconstructed values. This preferred embodiment is based on the insight that the method works best when a sequence of sharp edges is encountered, such as is typically the case in text and graphics. Text typically has a background color and a contrasting text part. Often the background is white and the text is black, but different background and text colors may be used, such as for instance red on a white background. It is then advantageous to provide an update of the fixed values. The values for the update are, as will be explained below, obtainable from the previously reconstructed values. An update of the fixed value(s) may, within the broadest concept of the invention, be done by means of an update signal separate from the reconstructed values. Preferably, however, the fixed value(s) are updated from previously reconstructed values.

The invention, in all its embodiments may be used for any data which uses a predictive coding method. Thus, it may be used for e.g. a monochromatic image, or for a color image.

It is well known that data for color images are comprised of different colors data. The invention may be used for any of the data composing the image data, but is preferably for all data composing the color image data.

The invention is also embodied in any computer program comprising program code means for performing a method in accordance with the invention when said program is run on a computer as well as in any computer program product comprising program code means stored on a computer readable medium for performing a method in accordance with the invention when said program is run on a computer, as well as any program product comprising program code means for use in a system in accordance with the invention, for performing the action specific for the invention.

These and further aspects of the invention will be explained in greater detail by way of example and with reference to the accompanying drawings, in which

### SHORT DESCRIPTION OF THE DRAWINGS

FIGS. 1 and 2 illustrate a conventional DPCM coding method illustrating respectively coding (FIG. 1) and decoding (FIG. 2);

FIGS. 3 and 4 illustrate a compound image;

FIG. 5 illustrates text parts of a compound image;

FIGS. 6 and 7 illustrate an embodiment of the invention

FIGS. 8 and 9 illustrate a further embodiment of the invention.

The figures are not drawn to scale. Generally, identical components are denoted by the same reference numerals in the figures.

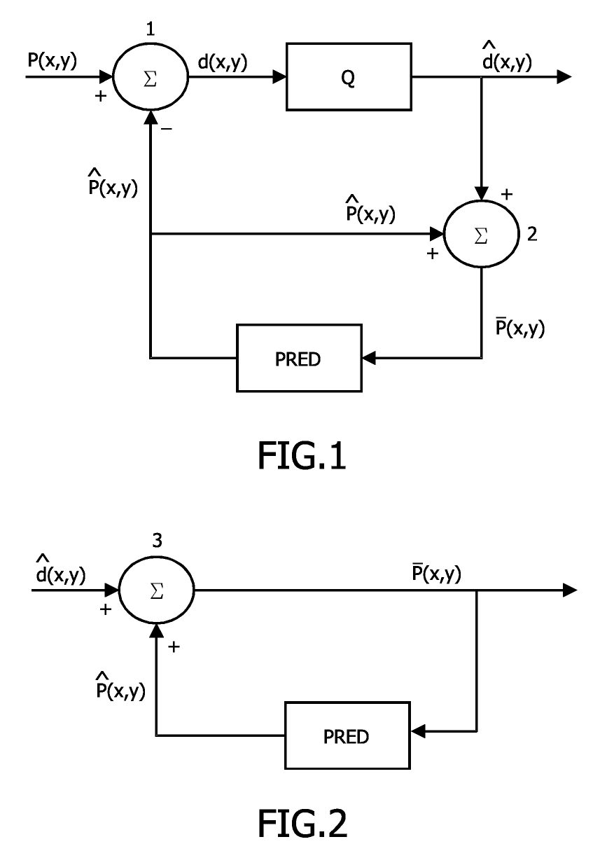

FIGS. 1 and 2 illustrate by means of block diagrams a conventional DPCM coding method. FIG. 1 illustrates the encoder part, FIG. 2 the decoder part of the method. These figure also schematically illustrate an encoder and a decoder for a system. In predictive coding, also called differential coding, the transmitter and the receiver process the data (e.g. image data) in some fixed order (e.g. raster order, row by row and left to right within a row). The current data (e.g. the current pixel) is predicted from the preceding data, which have been reconstructed. The difference between the current data P(x,y) and its predicted value \hat{P}(x,y) is the prediction error d(x,y) which is calculated in subtractor 1. The prediction error is then quantized in quantizer Q giving a quantized prediction error \hat{d}(x,y), encoded and transmitted to the receiver. The quantized prediction error therefore is a difference value. The quantized prediction error is fed to adder 2 in which it is added to predicted value \hat{P}(x,y), giving reconstructed value P̅(x,y).

This reconstructed value P̅(x,y) is fed to predictor PRED in which, using delays the next predicted value \hat{P}(x,y) is predicted. In the decoder side the reverse process is performed. The underlying notion beyond predictive coding is that to remove mutual redundancy between successive data, e.g. between successive pixels on a row of an image by coding difference values, i.e. prediction errors. If the prediction is well designed, then the distribution of the prediction error is concentrated near zero and has substantially lower entropy than the entropy of the original image.

The end result of the decoded signal is, as is shown in FIG. 2, not P(x,y) but P̅(x,y), i.e. the reconstructed data and thus differences between the original image and the DPCM coded and subsequently decoded image arise. When large differences values (large values for d(x,y)) between pixels occur, such as for instance when an edge is present in the image, the DPCM method may result in oscillations (overshoot). This leads to a smearing of the edge. This is in particular apparent when the DPCM method calculates the current prediction value using more than one previous prediction value as in the method described in EP 0 599 124. In the described prior art document EP 0 599 124 an attempt has been made to reduce the occurrence of such oscillations for such methods by either deriving the prediction value from more than one previous prediction value or, in case an edge is encountered from only one previous prediction value. However, the problem still exists.

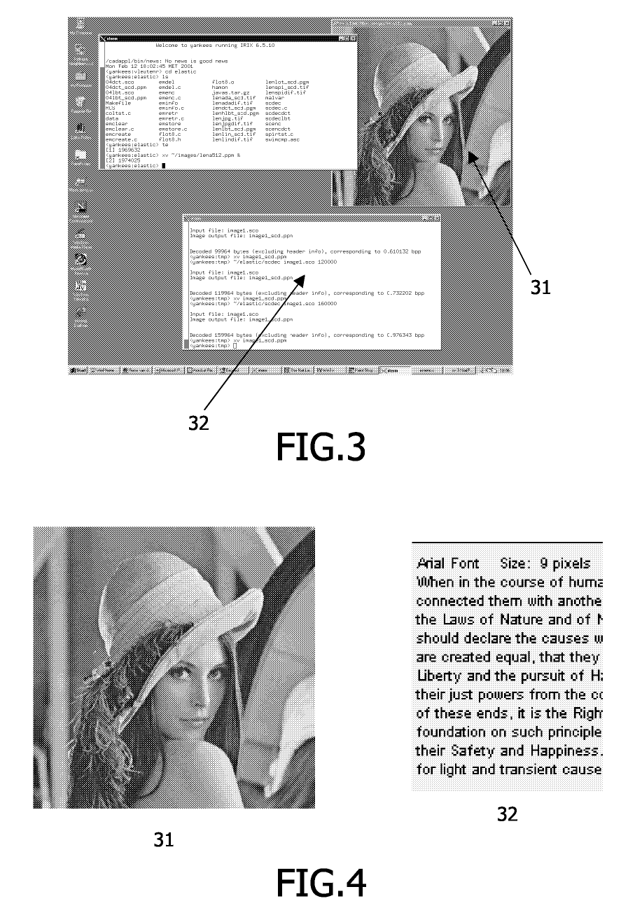

The inventors have found that smearing of the edges is in particular objectionable in compound images. For application in image (or video) compression, DPCM is usually optimized for the compression of “natural” images (such as typical holiday pictures and movies). However, with the advance of digital technology and the associated convergence that is occurring between the CE and PC domains, more and more “compound” images are appearing (for example in games). Such images consist of a mix of natural image content and graphics or text (such as sub-titles). The smearing of the edge is particularly objectionable, since the edges are very sharp, so the overshoot is relatively large and before the edge can converge the next edge occurs. This is a fundamental problem, which is not resolved by the known method, which merely exchanges one type of DPCM method by another when an edge is encountered. FIGS. 3 and 4 illustrate a compound image, comprising a natural image 31 as well as text parts 32. The natural images usually have all kinds of grey tones, whereas the text parts are usually black and white, or at least have two distinct values, a high and a low value. The inventors have realized that it is possible by a simple method to substantially increase the image quality of the text parts without substantially reducing the image quality of the natural image content of the compound image.

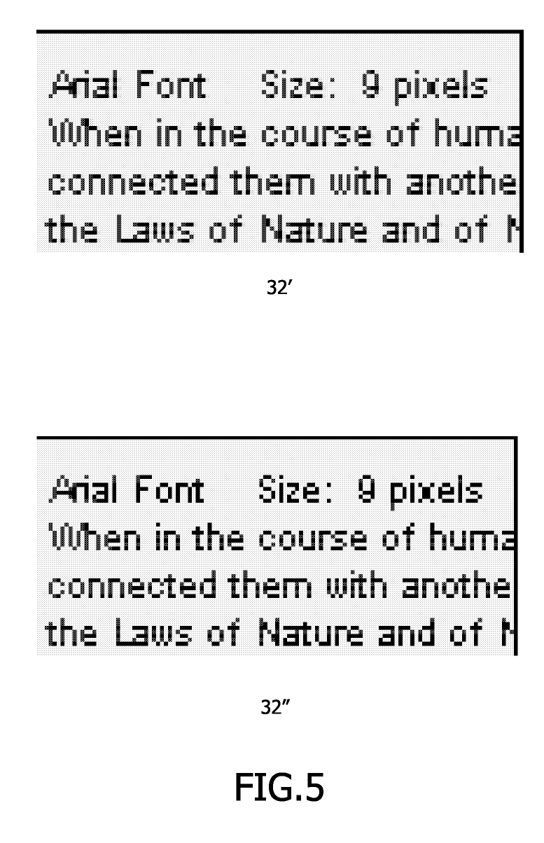

FIG. 5, upper part, illustrates the problem of standard DPCM methods for text parts. The text shows a ‘ghost’ text. The oscillations due to the DPCM method give raise to a grey value next to the transition between black white and the end of each letter.

The invention aims to provide a method in which the problem is reduced in a more fundamental manner.

To this end the method is characterized in that the method comprises a step in which the difference value is compared to a threshold and, if the difference value exceeds the threshold, a fixed reconstructed value is taken.

The invention is based on the insight that it may be advantageous, e.g. if high differential values occur, to fix the value for P̅(x,y). For subtitles this may e.g. be white 255 or 240 value. Instead of coding differentially, the method in accordance with the invention thus codes absolute, i.e. the value for P̅(x,y) is an absolute fixed value. Bypassing the DPCM-loop eliminates the oscillations. FIG. 5, bottom part, shows the result of the method. The ‘ghost’ text has disappeared. Going from left to right edges will be encountered at the beginning and the end of each letter. Going from black to white at an end of a letter a large difference value d(x,y), and after quantization a large quantized error \hat{d}(x,y) is found. This large difference value \hat{d}(x,y) exceeds a threshold, and thus in accordance with the invention the switch is activated and a fixed absolute value, i.e. pure white 255 or 240 in this example is inserted. If, indeed, the part of the data relate to a text part, the next actual value will be pure white 255 or 240, equal to the coded value.

The compression of text and graphics is in the method in accordance to the invention improved by replacing the normal output of the DPCM decoder by a fixed value in case the signal meets a criterion, in the examples a large discrepancy occurs between the predicted signal value and the actual signal value, i.e. a difference value above a threshold is detected. Such a large discrepancy, or prediction error, typically occurs on a discontinuity, or edge, in the image signal. Especially text is characterized by many such steep edges, which occur on any change from text character samples to background samples and vice versa. The central idea of the algorithm is thus to replace the regular DPCM output by a fixed value (Hival or Loval) representing the correct text or background color, in case of text compression, or more generally by the correct foreground or background color in case of graphics or natural image content compression. In text the fixed values often stand for black and white.

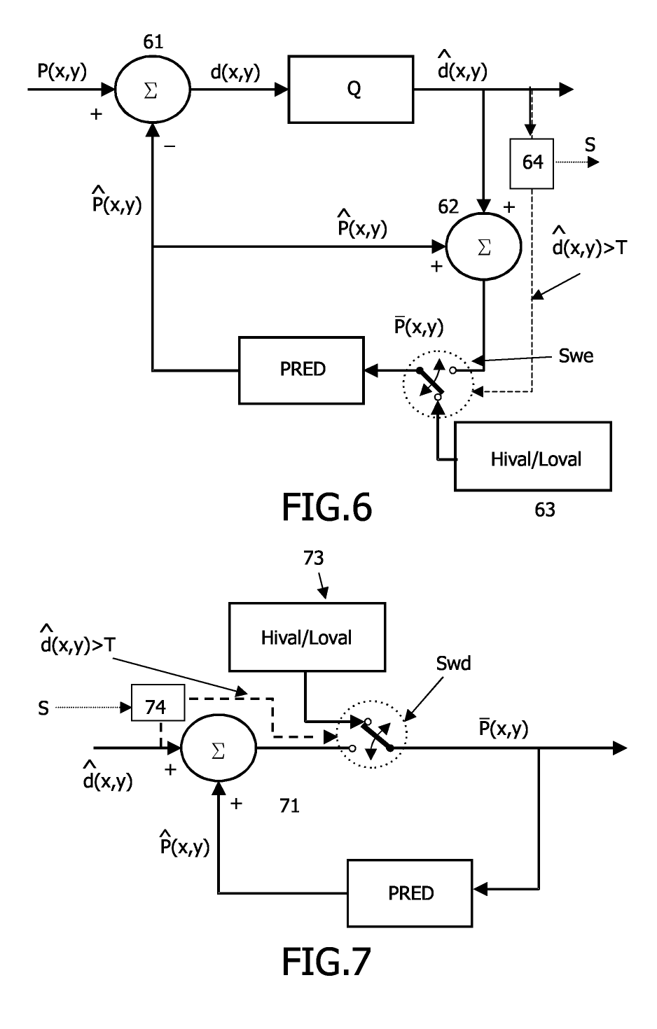

FIGS. 6 and 7 illustrate a simple embodiment of the method in accordance with the invention. The generator 61 generates a difference value d(x,y). The generator 62 in the encoder and generator 71 in the encoder generate a reconstructed value P̅(x,y). Memories 63, 73 store the fixed value Hival, Loval and encoder switch Swe is controlled by controller 64. In this example the switch is triggered when the difference value is beyond a threshold value T. The encoder and decoder comprise controllers 64, 74 for controlling the switches Swe and Swd in respectively the encoder and decoder. The controllers in embodiments compare indicator data, presented at inputs of the controllers, in the figures the difference values for the encoder and either the difference values or the switching signal S for the decoder, to one or more criteria. In the figures it is schematically indicated that the differences values are compared to a threshold T.

Part of the block diagrams for the coding and decoding are the same as in FIGS. 1 and 2. The difference is the provision of switches Swe and Swd in respectively the encoder and decoder, which are controlled by controllers 64 and 74. The controllers 64 and 74 have an input for indicator data. The input determines whether the switches Swe and Swd are triggered. The controller 64 has an input for data, in this case the difference values \hat{d}(x,y). The switch Swe is triggered when the input data meet a criterion, for instance if the difference values is larger than a threshold T. “Being larger than a threshold’ may mean that a positive value is larger than a positive threshold, or a negative value is smaller than a negative threshold. If the switch is triggered, the reconstructed value is taken to be a fixed high value (Hival) or a fixed low value (Loval) dependent on the sign of \hat{d}(x,y). This method step is performed in decoding as well as in encoding. The encoder may have means for generating a separated switching signal S. If this is the case, the controller 74 has an input for said switching signals S. Provision of a separate switching signal S has the disadvantage of requiring more data transfer, and introduction of novel data, since a separate signals has to be included in the data. It may have, however, the advantage of a more robust control of switch Swd. The advantage is also that the encoder does not need to know the algorithm used in the encoder to control the switch Swe, thus enabling for instance, a change in the switching algorithm used in the encoder, without a need for changing the decoder, or a standard decoder for several types of encoders using different algorithm or different input data.

In this simple embodiment the high and low values Hival and Loval are fixed values. It is remarked that, especially in the decoder part of the invention, the criterion in its most general form is that the decoder is provided with a signal that indicates that the switch is to be activated. A simple arrangement is that the incoming difference values meet a criterion and, if it does, the switch Swe, Swd is activated. As explained above, it is also possible that, in the encoder part, when the switch Swe is activated a “switch’ signal S is generated which has no direct relation to a difference value or is of a different type, which ‘switch signal’ S is sent in the bit-stream, and which ‘switch’ signal is recognizable by the decoder as the ‘switch’ signal for the decoder. All that is needed is that the data at an input of the controller 74 meet a criterion (in this case that there is a ‘switch’ signal S). Once this criterion is met, the switch Swd is activated. When use is made of separately recognizable ‘switch signals’ they need not necessarily be positioned in the bit stream at a position corresponding to a switching instant, as long as the decoder is given information to identify the switching instant.

Of course, any advantage may, in circumstances, lead to a disadvantage. The method of the invention increases the quality of text or graphics, but it could perceivably reduce the image quality of natural images.

However, it is an insight that the above-mentioned large prediction errors normally occur only occasionally in natural images, so the compression/quality of natural images is hardly affected by the special treatment of this case as was verified experimentally.

In embodiments the encoder is arranged to sent, with the data stream an indicating signal indicating that the encoder comprises an operative controller and switch.

This preferred embodiment allows the following:

The decoder may be provided with a means to recognize that the method in accordance with the invention is used or not. By enabling or disenabling the controller and the switch the decoder can operate in a conventional manner (when such indicating signal is absent) or in accordance with the invention (in case such indicating signal is present). The decoder is then capable of decoding data generated by conventional methods and encoders as well as by a method and encoder in accordance with the invention. Such a decoder can decode conventional data streams as well data streams generated by a method or encoder in accordance with the invention, without appreciable loss of quality.

“Operative controller and switch” cover embodiments in which the encoder has only one mode of operation, i.e. always encodes in accordance with the invention, but also covers encoders which are capable of operating in two modes of operation, one in which the switch is operative and one in which the conventional method is used. As explained above and below, the method in accordance with the invention is particularly advantageous when composite images are coded/decoded. The to be encoded data (P(x,y) may be provided with an type indication of the type of image (e.g. compound or natural image) or more in general the type of data to be encoded. Depending on such type indication the controller and switch made be made operative or not.

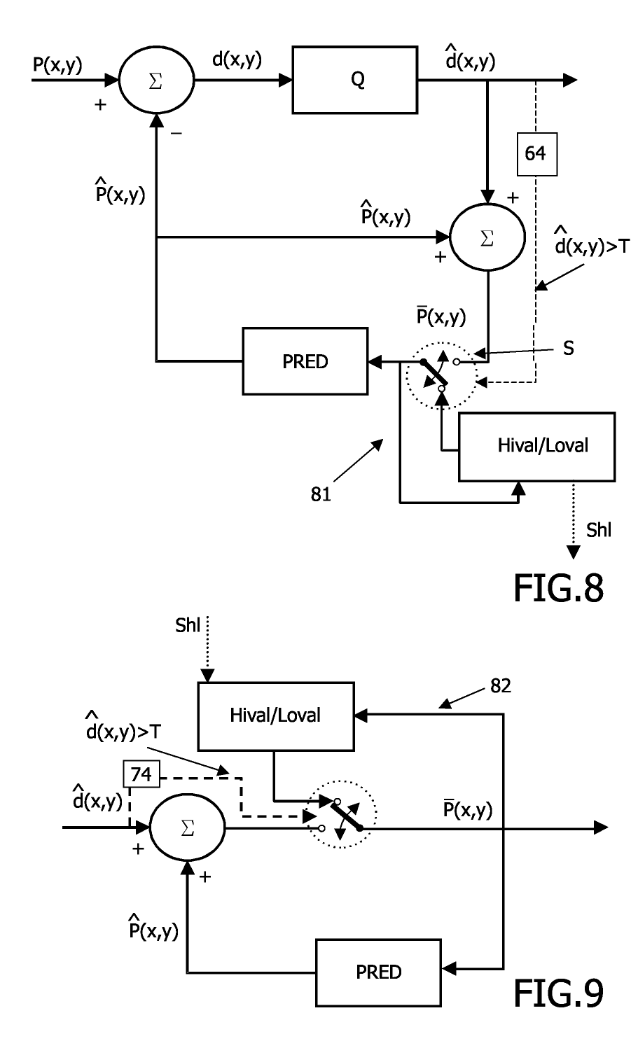

In the simple embodiment of FIGS. 6 and 7 the fixed values for the reconstructed values cannot be adapted. In preferred embodiments of the invention the fixed values are adaptable. FIGS. 8 and 9 illustrate such preferred embodiment for the coding (FIG. 8) and decoding (FIG. 9) method. Said figures also schematically illustrate an encoder and a decoder for a system.

The method and algorithm of the preferred embodiment replaces, by adaptively changing/selecting, the regular DPCM output by a value equivalent to or at least very close to the correct text or background color, in case of text compression, or more generally by the correct foreground or background color in case of graphics or natural image content compression. These replacement colors are determined according to replacement rules which determine, based preferably on previously determined reconstructed values, the novel fixed values. In FIGS. 8 and 9 this is shown by means of arrows.

The following test has been performed:

An implementation for the invention was made for a one-dimensional DPCM compression module suitable for compression of compound images, either by itself or as one of a multitude of modules/methods in a larger compression system. As a prediction for the current sample, the sample immediately preceding it is used; the first sample of a line is sent directly in uncompressed form.

A symmetric quantizer with 16 output levels was used, which requires log2(16)=4 bits per symbol if no further entropy coding is applied, thus providing a factor of 2 compression of the 8-bit input signal. The quantizer representation levels and decision intervals were first engineered to provide good visual quality on compound images without using the invention. The resulting prediction error intervals are ±[0-5, 6-19, 20-35, 36-57, 58-85, 86-119, 120-159, 160-255], with the corresponding representation values (for the prediction errors) for each interval of ±[2, 12, 27, 46, 71, 102, 139, 207]. When the prediction error is exactly 0, the positive representation is chosen.

For applying the invention, whenever the highest prediction error interval/value was found, the output of the decoder (the reconstructed value P̅(x,y) is not taken to be the previous sample±207, but is instead selected as either a “high value” Hival or a “low value” Loval, depending on whether the prediction error is positive (high value is selected) or negative (low value is selected).

The high and low fixed, yet adaptable, values Hival and Loval are in preferred embodiment adapted according to the adaptation rules. In order to detect a stable or stabilizing output value, the high and low values may for instance be updated only if the current prediction error falls in the lowest intervals, i.e. ±[0-5], or if the current prediction error falls in an interval that is closer to 0 than the previous prediction error interval (i.e. the prediction error is getting smaller). If the above conditions for update apply then the low value is set to the current output value in case that output value is smaller than 96 and the high value is set to the current output value in case that value is larger than 159 (so the low value must be in the range of the lowest 96 output values, 0-95, and the high value must be in the range of the highest 96 output values, 160-255). The reason for choosing these ranges is that the prediction error can never fall in the highest interval of ±[160-255] in case the high and low values are not in the above-mentioned range (i.e. it is certain that the high value is not less than 160 and it is also certain that the low value is not more than 95). These rules provide an example for a method in which the values Hival and Loval are adaptable based on reconstructed values. A stable or stabilizing output value is detected using detecting rules on the basis of reconstructed values. Once, using these rules such an output level is established, these values are made the values Hival and Loval. The values Hival and Loval may be established in encoder as well as decoder by using the same algorithm.

However, it is also possible that the encoder uses an algorithm to establish the values Hival and Loval and the positions in the data stream at which said values changes, and that the values Hival and Loval are sent as separate data Shl in the data stream. In such embodiments the decoder does not need to know the algorithm by which the encoder has established the values Hival and Loval enabling the decoder to handle bitstream generated by encoder in accordance with the invention even if the encoders themselves use different algorithm to calculate Hival, Loval.

The following table gives the some results which compare the standard method to the method of the invention. As a measure of image quality the so-called PSNR (peak-signal-to-noise-ratio) for compressed images is calculated. The value for PSNR gives a crude measure for quality.

TABLE 1
PSNRs [dB] for regular DPCM and the proposed method

| | Regular DPCM | Proposed Method |
|---|---|---|
| Compound (FIG. 3) | 32.03 | 36.09 |
| Fonts (32) | 23.47 | 27.15 |
| Lena (31) | 38.13 | 38.13 |

The PSNR value for the picture 31 is not changed, but for the fonts 32 the PSNR value is greatly increased. The PSNR value for the compound FIG. 3 is also greatly increased. Various experiments with various colored texts parts and images has shown that the method substantially increases the quality of text parts, with the largest improvement being obtained for black and white texts, which are the most often used types of text, with no or only a very small negative effect on image parts of a compound image. The positive effects on text parts are clearly visible to the human eye, whereas any negative effect on image parts are not visible to the naked eye.

In short the invention may be described by:

In a method for coding and decoding indicator data (\hat{d}(x,y),S) are compared to a criterion (T). If the indicator data meet the criterion, an absolute value (Hival/Loval) is inserted instead of a predicted value based on differential coding. This amounts to a bypass of the differential coding loop, which reduces or eliminates oscillatory behavior in such loop, thereby reducing smearing of text parts of a compound image. The absolute values are preferably dynamically determined on the basis of previous predicted values.

The invention can be applied to improve DPCM compression of non-natural image content, in particular textual information. An application area is in embedded compression for reducing video bandwidth or (embedded) memory requirements in general and especially in one-dimensional DPCM as applied for e.g.:
compression of memory transfers (of image data) for bandwidth reduction,
compression for interface bus bandwidth reduction of image data sent to LCoS displays,
compression of the image memory in mobile display drivers.

The method, system, encoder and decoder in accordance with the invention may be used. Within the concept of the invention an ‘adder’ ‘quantizer’, ‘switch’, ‘predictor’, etc. is to be broadly understood and to comprise e.g. any piece of hard-ware (such an adder, switch), any circuit or sub-circuit designed for adding, quantizing, predicting etc. as described as well as any piece of soft-ware (computer program or sub program or set of computer programs, or program code(s)) designed or programmed to perform such tasks in accordance with the invention as a whole or a feature of the invention, whether in the form of a method or a system, as well as any combination of pieces of hardware and software acting as such, alone or in combination, without being restricted to the given exemplary embodiments.

It will be appreciated by persons skilled in the art that the present invention is not limited by what has been particularly shown and described hereinabove. The invention resides in each and every novel characteristic feature and each and every combination of characteristic features. Reference numerals in the claims do not limit their protective scope. Use of the verb “to comprise” and its conjugations does not exclude the presence of elements other than those stated in the claims. Use of the article “a” or “an” preceding an element does not exclude the presence of a plurality of such elements. For instance in the example a quantizer is used, which is a preferred embodiment. A particular type of quantizer is given in the example. The invention is not restricted to the use of the particular type of quantizer, nor, in its broadest sense, to the use of a quantizer. The invention is applicable to a DPCM method of coding, including any hybrid DPCM/DCT types of coding. In the example the quantized difference value is used to trigger the switch. Within the scope of the invention the switch could be triggered by any signal which is related to the condition that the difference value is above the threshold. For instance the switch S could be, in the encoder part, be triggered by the difference value d(x,y). What is required is that the switch S is triggered when the difference value exceeds a threshold value. “indicator data” within the concept of the invention is any data within the data stream that forms an input for controllers 64 (in the encoder part) or 74 (in the decoder part).

In the examples two different embodiments are shown in respect of the manner in which the fixed values Hival/Loval are determined. In one of these embodiments the fixed values are non-adaptable, for instance pure white and pure black, in the other embodiment the values are adaptable, i.e. they are adapted on the basis of the predicted values. It is also possible, especially when the data is organized in distinguishable units (such as lines or frames) that separate data are coded and decoded which indicate the Loval and Hival value for the particular line. In the coding part of the method the ‘best’ value for Hival and Loval would be determined and signals corresponding to said values would be sent with the bitstream. At the decoding end these values are decoded and the corresponding Hival and Loval values are implemented.

1. A method of encoding data using a predictive coding method, in which predictive encoding method a difference value (\hat{d}(x,y)), representing a difference between a predicted value (\hat{P}(x,y)) and an actual value (P(x,y)), is generated wherein the difference value (\hat{d}(x,y)) and a predicted value (\hat{P}(x,y)) are used to generate a reconstructed value Which reconstructed value ( P̅(x,y)) is used to predict a novel predicted value (\hat{P}(x,y)), wherein indicator data (\hat{d}(x,y)) are compared to a criterion (T) and, if the indicator data meet the criterion, a fixed value (Hival, Loval) is inserted for a value ( P̅(x,y)) reconstructed from the difference value and a predicted value.

2. A method of encoding data as claimed in claim 1, wherein the difference value (\hat{d}(x,y)) is compared to a criterion (T) and, if the difference value meets the criterion, a fixed value (Hival/Loval) is inserted for a value ( P̅(x,y)) reconstructed from the difference value and a predicted value.

3. A method of encoding data as claimed in claim 1, wherein a switching signal (S) is generated, indicating a switch from a fixed value to a reconstructed value and/or vice versa.

4. A method of decoding data generated by a predictive coding method, said data comprising a difference value (\hat{d}(x,y)) in which decoding method the difference value (e,cir d(x,y)) is used to generate, on the basis of a predicted value (\hat{P}(x,y)) a reconstructed value ( P̅(x,y)) which reconstructed value is used to predict a novel predicted value (\hat{P}(x,y)) wherein indicator data (\hat{d}(x,y),S) are compared to a criterion and, if the indicator data meet the criterion, a fixed value (Hival, Loval) is inserted for a value ( P̅(x,y)) reconstructed from the difference value and a predicted value.

5. A decoding method as claimed in claim 4, wherein the method comprises the difference value (\hat{d}(x,y)) is compared to a criterion (T) and, if the criterion is met, a fixed value (Hival/Loval) is coded instead of a value reconstructed from the difference value and a predicted value.

6. A method as claimed in claim 2, wherein a fixed absolute value (Hival, Loval) is inserted only when a difference value of a particular sign, either positive or negative, meets the criterion.

7. A method as claimed in claim 2, wherein a fixed absolute value (Hival, Loval) is inserted when a difference value of any sign meets the criterion.

8. A method as claimed in claim 2 wherein the criterion is that the difference value is above a threshold (\hat{d}(x,y)>T).

9. A method as claimed in claim 1, wherein the method comprises a step in which the fixed values (Hival, Loval) are updated (81, 82).

10. A method as claimed in claim 9 wherein the fixed values are updated from previously reconstructed values ( P̅(x,y)).

11. An encoder for coding data using a predictive coding method, the encoder comprising a generator (61) for generating a difference value (\hat{d}(x,y)) between a predicted value (\hat{P}(x,y)) and an actual value (P(x,y)) and a generator (62) for generating from said difference value (\hat{d}(x,y)) a reconstructed value ( P̅(x,y)) and a predictor (PRED) for predicting a predicted value (\hat{P}(x,y)) wherein the encoder comprises a controller (64) and a switch (Swe) wherein the controller (64) controls the switch (Swe) to switch to and from inserting a fixed value (Hival, Loval) for a value ( P̅(x,y)) reconstructed from the difference value and a predicted value.

12. An encoder as claimed in claim 11, wherein the controller is arranged to compare a difference value (\hat{d}(x,y)) to a criterion (T).

13. An encoder as claimed in claim 12, wherein the criterion is a threshold (T)

14. An encoder as claimed in claim 11, wherein the controller is arranged to generate a switching signal (S), indicating operation of the switch (Swe).

15. A decoder for decoding data using a predictive coding method, the decoder comprising a generator (71) for generating from a difference value (\hat{d}(x,y)) a reconstructed value ( P̅(x,y)) and a predictor (PRED) for predicting a predicted value (\hat{P}(x,y)), the decoder comprising a controller (74) to control a switch (Swd) to switch to and from inserting a fixed value (Hival, Loval) for a value ( P̅(x,y)) reconstructed from the difference value and a predicted value.

16. A decoder as claimed in claim 15, wherein the controller (74) is arranged to compare data (\hat{d}(x,y),S) to a criterion.

17. A decoder as claimed in claim 15, wherein the controller is arranged to detect the presence of a switching signal (S).

18. A decoder as claimed in claim 15 wherein the decoder has means to disenable the controller (74) and switch (Swd).

19. (canceled)

20. (canceled)

21. (canceled)
